(19) United States
(12) Patent Application Publication
(10) Pub. No.: US 2024/0234330 A9
(43) Pub. Date: Jul. 11, 2024

(54) SEMICONDUCTOR DEVICE AND METHOD FOR MANUFACTURING SEMICONDUCTOR DEVICE

(71) Applicant: POWER MASTER SEMICONDUCTOR CO., LTD., Cheongju-si (KR)

(72) Inventors: Sangwoo PAK, Gimpo-si (KR); Hong-ki Kim, Incheon (KR)

(21) Appl. No.: 18/381,263

(22) Filed: Oct. 18, 2023

(30) Foreign Application Priority Data
Oct. 25, 2022 (KR) 10-2022-0138689
Dec. 12, 2022 (KR) 10-2022-0172894

(51) Int. Cl. H01L 23/544; H01L 21/304; H01L 21/66; H01L 21/78

(52) U.S. Cl. CPC H01L 23/544; H01L 21/304; H01L 21/78; H01L 22/20; H01L 2223/5446

(57) ABSTRACT

A semiconductor device and a method for manufacturing the semiconductor device are provided. The method for manufacturing the semiconductor device may include providing a substrate, forming an epitaxial layer on the substrate, defining a scribe line layer in the epitaxial layer, forming an upper electrode layer on the epitaxial layer and the scribe line layer, etching a portion of the upper electrode layer to expose the scribe line layer, forming a main passivation layer on the upper electrode layer, and forming an additional passivation layer on the scribe line layer.

### CROSS-REFERENCE TO RELATED APPLICATION

This application claims priority to and the benefit of Korean Patent Application No. 10-2022-0138689 filed in the Korean Intellectual Property Office on Oct. 25, 2022, and Korean Patent Application No. 10-2022-0172894 filed in the Korean Intellectual Property Office on Dec. 12, 2022, the entire contents of which are incorporated herein by reference.

### BACKGROUND OF THE INVENTION

### (a) Field of the Invention

The present disclosure relates to a semiconductor device and a method for manufacturing the semiconductor device.

### (b) Description of the Related Art

In the packaging process which is included in the semiconductor back-end process, dicing may be performed to divide wafers into individual hexahedral chips, and sawing wafer plates into individual chips is called die sawing. Specifically, on a wafer, a number of IC chips, i.e., dies having the same size are repeatedly arranged, and the dies are disposed so as to be spaced apart from one another at regular intervals, which are called scribe lines

After wafer processing is completed, the dies are cut out to make chips, and when the dies are cut out by a diamond saw, the scribe lines may provide widths for avoiding cracking.

### SUMMARY OF THE INVENTION

The present disclosure attempts to provide a semiconductor device and a method for manufacturing the semiconductor device capable of preventing occurrence of sparks by raising the threshold voltage of an insulator between an upper electrode layer and a scribe line layer.

A method for manufacturing a semiconductor device according to an example embodiment may include providing a substrate, forming an epitaxial layer on the substrate, defining a scribe line layer in the epitaxial layer, forming an upper electrode layer on the epitaxial layer and the scribe line layer, etching a portion of the upper electrode layer to expose the scribe line layer, forming a main passivation layer on the upper electrode layer, and forming an additional passivation layer on the scribe line layer.

In some example embodiments, the method may further include forming active layers and termination layers on the epitaxial layer, and forming the upper electrode layer may include forming the upper electrode layer on the active layers and the termination layers.

In some example embodiments, the method may further include etching a portion of the upper electrode layer to expose some portions of the termination layers, and forming the main passivation layer may include forming the main passivation layer on the upper electrode layer and the exposed portions of the termination layers.

In some example embodiments, the method may further include etching a portion of the upper electrode layer to expose a portion of the epitaxial layer, and forming the main passivation layer may include forming the main passivation layer on the upper electrode layer, the exposed portions of the termination layers, and the exposed portion of the epitaxial layer.

In some example embodiments, the method may further include etching a portion of the main passivation layer to expose a portion of the upper electrode layer.

In some example embodiments, the method may further include removing the substrate through a grinding process.

In some example embodiments, the method may further include forming a lower electrode layer on the surface from which the substrate has been removed by the grinding process.

In some example embodiments, the method may further include performing a sawing process along the additional passivation layer.

In some example embodiments, the method may further include performing an EDS (electrical die sorting) process or mapping measurement before the sawing is performed.

In some example embodiments, forming the additional passivation layer may include deposing SiO₂ on the scribe line layer to a predetermined thickness to form the additional passivation layer.

A semiconductor device according to an example embodiment may include a lower electrode layer, an epitaxial layer that is formed on the lower electrode layer, an upper electrode layer that is formed on a portion of the epitaxial layer, a main passivation layer that is formed on another portion of the epitaxial layer and a portion of the upper electrode layer, a first scribe line layer that is formed on a first side of the epitaxial layer on the lower electrode layer, a first additional passivation layer that is formed on the first scribe line layer, a second scribe line layer that is formed on a second side of the epitaxial layer on the lower electrode layer, and a second additional passivation layer that is formed on the second scribe line layer.

In some example embodiments, on the epitaxial layer, active layers may be formed, and on the active layer, the upper electrode layer may be formed.

In some example embodiments, on the epitaxial layer, termination layers may be formed, and on some portions of the termination layers, the upper electrode layer may be formed, and on the other portions of the termination layers, the main passivation layer may be formed.

In some example embodiments, the first additional passivation layer and the second additional passivation layer may be formed by deposing SiO₂ on the first scribe line layer and the second scribe line layer to a predetermined thickness.

According to the example embodiments, the structure in which the additional passivation layers are formed on the scribe line layers makes it possible to raise the threshold voltage of an insulator between the upper electrode layer and the scribe lines. Accordingly, when an EDS process or mapping measurement is performed on the semiconductor device, even if a high voltage of hundreds to thousands of volts is applied to the lower electrode layer, it is possible to prevent occurrence of sparks. Therefore, it is possible to prevent the semiconductor device from failing to reach a normal withstand voltage or being damaged while current flows by sparks.

### BRIEF DESCRIPTION OF THE DRAWINGS

FIG. 1 is a view for explaining a semiconductor device according to an example embodiment.

FIG. 2 is a view for explaining semiconductor devices according to an example embodiment.

FIG. 3 to FIG. 10 are views for explaining methods for manufacturing a semiconductor device according to an example embodiment.

### DETAILED DESCRIPTION OF THE EMBODIMENTS

In the following detailed description, only certain example embodiments of the present invention have been shown and described, simply by way of illustration. However, the present invention can be variously implemented and is not limited to the following example embodiments. The drawings are to be regarded as illustrative in nature and not restrictive. Like reference numerals designate like elements throughout the specification.

Throughout the specification and the claims, unless explicitly described to the contrary, the word “comprise”, and variations such as “comprises” or “comprising”, will be understood to imply the inclusion of stated elements but not the exclusion of any other elements.

Power MOSFETs (metal oxide semiconductor field effect transistors) may be used as switching elements, and typically require low on-resistance, high breakdown voltage, and high switching speed. Particularly, super junction MOSFETs which are included in the typical examples of MOSFETs with high withstand voltage are a type of Si-MOSFETs and are superior in high-speed switching operation at relatively low power as compared to IGBTs (insulated gate bipolar transistors). Example embodiments will be described mainly with examples related to super junction semiconductor devices; however, the technical idea of the present invention is not limited thereto, and the technical idea of the present invention may also be applied to other types of power switch technologies including IGBT devices, Schottky rectifiers, various types of bipolar switches, and various types of thyristors and rectifiers. Hereinafter, the term “semiconductor device” may refer to a super junction MOSFET or a super junction semiconductor device, unless otherwise defined.

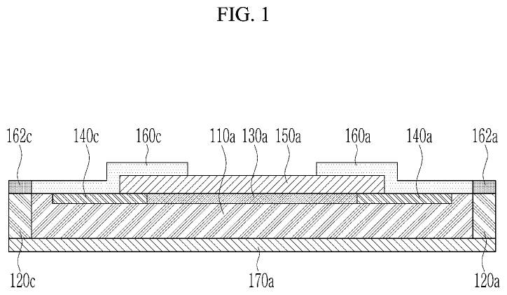

FIG. 1 is a view for explaining a semiconductor device according to an example embodiment.

Referring to FIG. 1, a semiconductor device according to an example embodiment may include a lower electrode layer 170a, an epitaxial layer 110a, an active layer 130a, termination layers 140a and 140c, an upper electrode layer 150a, and main passivation layers 160a and 160c. And the semiconductor device may further include scribe line layers 120a and 120c and additional passivation layers 162a and 162c.

The active layer 130a may determine a primary function of the semiconductor device. The active layer 130a may include a plurality of P fillers arranged at intervals along one direction, and N fillers formed between the plurality of P fillers. Meanwhile, the termination layers 140a and 140c may improve the breakdown voltage of the semiconductor device. The termination layers 140a and 140c may include the plurality of P fillers arranged at intervals along one direction and the N fillers formed between the plurality of P fillers. Although not shown in the drawings, between the active layer 130a and the termination layer 140a and between the active layer 130a and the termination layer 140c, frame layers may be additionally formed, and the frame layers may correspond to transition areas that are disposed between the active layer 130a and the individual termination layers 140a and 140c. Even in the frame layers, a plurality of P fillers arranged at intervals along one direction and N fillers formed between the plurality of P fillers. Of course, the internal layout of areas with the p type conductivity and areas with the n type conductivity in the active layer 130a and the termination layers 140a and 140c may be changed depending on specific implementation purposes.

Based on the upper surface of the semiconductor device, the termination layers 140a and 140c may be formed so as to surround the active layer 130a. In some example embodiments, the termination layers 140a and 140c may be formed so as to surround the frame layers, and the frame layers may be formed so as to the active layer 130a.

The epitaxial layer 110a may be formed on the lower electrode layer 170a. The epitaxial layer 110a may refer to, for example, an epitaxial layer formed on the substrate 100 and doped with a high concentration of N-type impurities.

The upper electrode layer 150a may be formed on a portion of the epitaxial layer 110a. In other words, the upper electrode layer 150a may cover a portion of the upper surface of the epitaxial layer 110a and expose the other portion. Specifically, the upper electrode layer 150a may completely cover the active layer 130a formed on the epitaxial layer 110a. In other words, on the active layer 130a, the upper electrode layer 150a may be formed. Meanwhile, the upper electrode layer 150a may cover only some portions of the termination layers 140a and 140c formed on the epitaxial layer 110a. In other words, on some portions of the termination layers 140a and 140c, the upper electrode layer 150a may be formed, and the other portions of the termination layers 140a and 140c may be exposed.

The main passivation layers 160a and 160c may be formed of insulators. The main passivation layers 160a and 160c may be formed on the exposed portion of the epitaxial layer 110a and some portions of the upper electrode layer 150a. Specifically, the main passivation layers 160a and 160c may be formed so as to cover the exposed portion of the epitaxial layer 110a, the exposed portions of the termination layers 140a and 140c and some portions of the upper electrode layer 150a. In other words, on the exposed portions of the termination layers 140a and 140c, the main passivation layers 160a and 160c may be formed.

The scribe line layers 120a and 120c may be formed on both sides of the epitaxial layer 110a on the lower electrode layer 170a. Specifically, the first scribe line layer 120a may be formed on a first side of the epitaxial layer 110a on the lower electrode layer 170a, and the second scribe line layer 120c may be formed on a second side of the epitaxial layer 110a on the lower electrode layer 170a, and the first side and the second side may correspond to opposite sides with respect to the epitaxial layer 110a. Here, the scribe line layers 120a and 120c may be layers that remain after the sawing process, i.e., dicing has been completed, rather than being cut away by a diamond saw.

The additional passivation layers 162a and 162c may be formed on the scribe line layers 120a and 120c. Specifically, the first additional passivation layer 162a may be formed on the first scribe line layer 120a, and the second additional passivation layer 162c may be formed on the second scribe line layer 120c. Here, the additional passivation layers 162a and 162c may be layers that remain after the sawing process, i.e., dicing has been completed, rather than being cut away by a diamond saw.

The additional passivation layers 162a and 162c may be oxide films, nitride films contain an insulating material such as an oxide-based insulating material, a nitride-based insulating material, or the like, having high dielectric strength so that it is possible to expect a sufficient of preventing sparks even when the additional passivation layers are thin. In some example embodiments, the additional passivation layers 162a and 162c may have a predetermined thickness and contain SiO₂. In some example embodiments, the additional passivation layers 162a and 162c may have a thickness of 2.0 μm and contain SiO₂.

When the additional passivation layers 162a and 162c are formed by depositing SiO₂ to a thickness of 2.0 μm, it is possible to prevent occurrence of sparks when the voltage of up to 2,200 V is applied between the upper electrode layer 150a and the lower electrode layer 170a. Specifically, a dielectric breakdown voltage may be calculated by multiplying a dielectric strength with a distance (or a length, a thickness, etc.) as follows.

Dielectric Breakdown Voltage (V)=[Dielectric Strength (V/cm)]*[Distance (cm)]

In the semiconductor device structure in FIG. 1, when the distance between the left side surface of the main passivation layer 160a and the left side surface of the additional passivation layer 162a is designed to be 200 μm and the thickness of the additional passivation layer 162a is designed to be 2.0 μm, the maximum withstand voltage may be calculated as follows.

| | Dielectric | | Dielectric |
|---|---|---|---|
| | Strength | Distance | Breakdown Voltage |
| Film | [V/cm] | [um] | (V) |
| Air | 3.0E+04 | 200 | 600 |
| SiO₂ | 8.0E+06 | 2.0 | 1600 |

| | |
|---|---|
| TOTAL | 2200 |

Since when a high voltage is applied to the lower electrode layer 170a, the same voltage is applied to the scribe line layer 120a, and there is the additional passivation layer 162a with the thickness of 2.0 μm formed by depositing SiO₂ in the path between the upper electrode layer 150a and the scribe line layer 120a in which sparks may occur, it is possible to improve the dielectric breakdown voltage up to 2,200 V. Accordingly, even when a voltage of up to 2,200 V is applied to the lower electrode layer 170a, it is possible to prevent occurrence of sparks. Therefore, it is possible to prevent the semiconductor device from failing to reach a normal withstand voltage or being damaged while current flows by sparks.

The case where a high voltage is applied as mentioned above may include a case of performing an EDS (electrical die sorting) process or mapping measurement before dicing is performed. In this case, there has been a problem that when a high voltage exceeding the dielectric breakdown voltage of air is applied, sparks occur. However, due to the structure according to the present example embodiment, even if a voltage of 2,200 V is applied while an EDS process or mapping measurement is performed, it is possible to prevent the semiconductor device from being damaged by occurrence of sparks, thereby increasing ease of handling and having a markedly favorable effect on product yield.

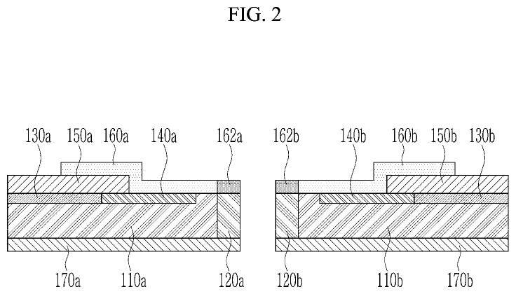

FIG. 2 is a view for explaining semiconductor devices according to an example embodiment.

Referring to FIG. 2, on a wafer, and another semiconductor device may be disposed adjacent to the semiconductor device in FIG. 1, and FIG. 2 shows that the semiconductor device in FIG. 1 and the other semiconductor device adjacent to it on the wafer are separate after dicing has been completed.

Specifically, the semiconductor device in FIG. 1 may include the lower electrode layer 170a, the epitaxial layer 110a, the active layer 130a, the termination layer 140a, the upper electrode layer 150a, and the main passivation layer 160a, and may further include the scribe line layer 120a on one side of the epitaxial layer 110a on the lower electrode layer 170a, and may further include the additional passivation layer 162a on the scribe line layer 120a. Here, the scribe line layer 120a and the additional passivation layer 162a may be layers that remain after the sawing process, i.e., dicing for separation from the adjacent semiconductor device has been completed, rather than being cut away by a diamond saw.

Meanwhile, the other semiconductor device adjacent thereto may include a lower electrode layer 170b, an epitaxial layer 110b, an active layer 130b, a termination layer 140b, an upper electrode layer 150b, and a main passivation layer 160b, and may further include a scribe line layer 120b on one side of the epitaxial layer 110b on the lower electrode layer 170b, and may further include an additional passivation layer 162b on the scribe line layer 120b. Here, the scribe line layer 120b and the additional passivation layer 162b could have formed the same layers along with the scribe line layer 120a and the additional passivation layer 162a before the sawing process was performed to separate the semiconductor device of FIG. 1, and may be layers that remain after the dicing has been completed, rather than being cut away by a diamond saw.

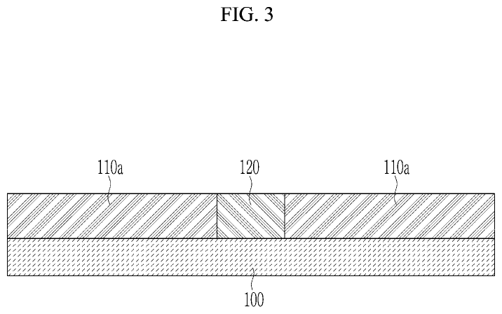

Hereinafter, a method for manufacturing a semiconductor device according to example embodiments will be described with reference to FIG. 3 to FIG. 10.

FIG. 3 to FIG. 10 are views for explaining methods for manufacturing a semiconductor device according to an example embodiment.

Referring to FIG. 3, a method for manufacturing a semiconductor device according to an example embodiment may include providing a substrate 100. Also, the above-mentioned method may include forming an epitaxial layer 110a and 110b on the substrate 100. Here, the epitaxial layer 110a and 110b may refer to an epitaxial layer doped with a high concentration of N-type impurities. Further, the above-mentioned method may include defining a scribe line layer 120 in the epitaxial layer 110a and 110b. Here, the scribe line layer 120 may provide a width for preventing cracking when dies are cut out with a diamond saw.

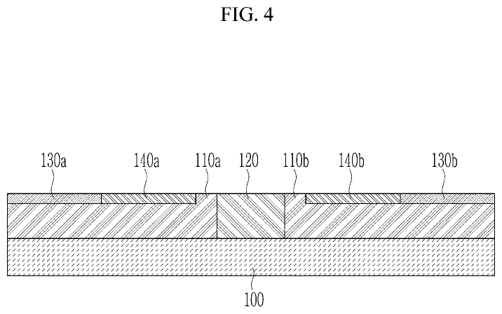

Referring to FIG. 4, the method for manufacturing the semiconductor device according to the example embodiment may further include forming active layers 130a and 130b and termination layers 140a and 140c on the epitaxial layer 110a and 110b. Specifically, on the wafer with the epitaxial layer 110a and 110b formed thereon, circuit patterns designed as the active layers may be formed by applying photoresist which is a photosensitive material, arranging a mask pattern, and performing exposure, and circuit patterns designed as the termination layers may be formed by repeating the same process using a different mask pattern.

In some example embodiments, the mask patterns may include a plurality of filler mask patterns which is used to form a plurality of P fillers and form N fillers between the plurality of P fillers. For example, among the plurality of filler mask patterns, a first filler mask pattern may be a pattern that is used to inject P-type impurities for forming P fillers in the active layers into the epitaxial layer 110a and 110b. Further, among the plurality of filler mask patterns, a second filler mask pattern may be a pattern that is used to inject N-type impurities for forming N fillers in the active layers into the epitaxial layer 110a and 110b. Meanwhile, among the plurality of filler mask patterns, a third filler mask pattern may be a pattern that is used to inject P-type impurities for forming P fillers in the termination layers into the epitaxial layer 110a and 110b, and among the plurality of filler mask patterns, a fourth filler mask pattern may be a pattern that is used to inject N-type impurities for forming N fillers in the termination layers into the epitaxial layer 110a and 110b.

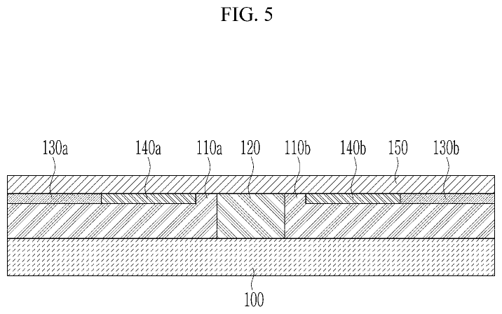

Referring to FIG. 5, the method for manufacturing the semiconductor device according to the example embodiment may include forming an upper electrode layer 150 on the epitaxial layer 110a and 110b and the scribe line layer 120. Specifically, the upper electrode layer 150 may be formed on the active layers 130a and 130b and the termination layers 140a and 140c, which may be performed through a process of deposing a metal.

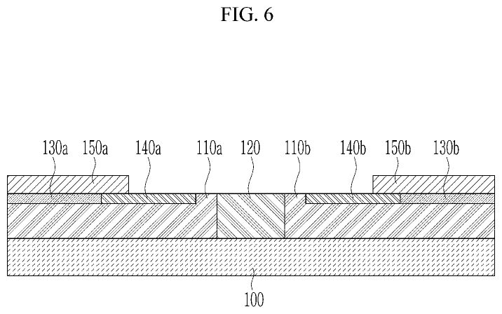

Referring to FIG. 6, the method for manufacturing the semiconductor device according to the example embodiment may include etching a portion of the upper electrode layer 150 and exposing the scribe line layer 120. Also, the above-mentioned method may further include etching a portion of the upper electrode layer 150 and exposing some portions of the termination layers 140a and 140b. Accordingly, the upper electrode layer 150a may cover the entire active layer 130a and cover a portion of the termination layer 140a, and the upper electrode layer 150b may cover the entire active layer 130b and cover a portion of the termination layer 140b. As described above, a portion of the upper electrode layer 150 may be etched such that a portion of the epitaxial layer 110a and 110b is exposed.

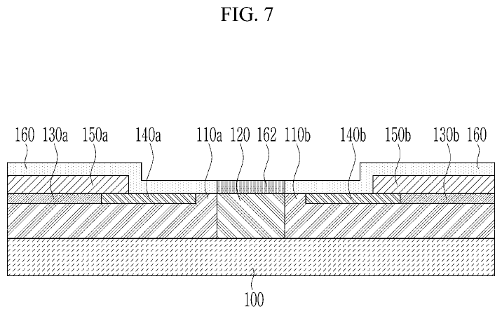

Referring to FIG. 7, the method for manufacturing the semiconductor device according to the example embodiment may include forming a main passivation layer 160 on the upper electrode layer 150. Specifically, on the upper electrode layer 150 and the exposed portions of the termination layers 140a and 140b, the main passivation layer 160 may be formed, and more specifically, on the upper electrode layer 150, the exposed portions of the termination layers 140a and 140b, and the exposed portion of the epitaxial layer 110a and 110b, the main passivation layer 160 may be formed. Further, the method for manufacturing the semiconductor device according to the example embodiment may include forming an additional passivation layer 162 on the scribe line layer 120.

In some example embodiments, forming the additional passivation layer 162 may include depositing SiO₂ on the scribe line layer 120 to a predetermined thickness to form the additional passivation layer 162.

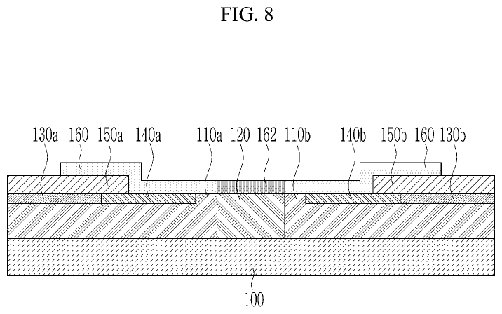

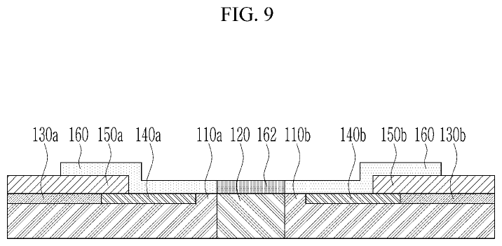

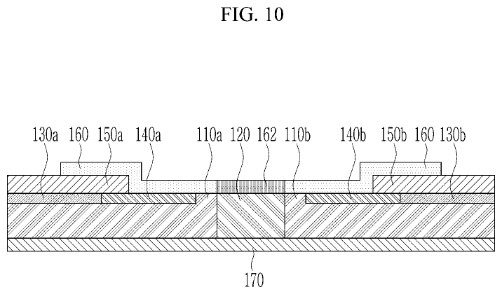

Referring to FIG. 8, the method for manufacturing the semiconductor device according to the example embodiment etches a portion of the main passivation layer 160 to expose a portion of the upper electrode layer (150a and 150b). Next, referring to FIG. 9, the method for manufacturing the semiconductor device according to the example embodiment may include removing the substrate 100 through a grinding process. Further, referring to FIG. 10, the above-mentioned method may include forming a lower electrode layer 170 on the surface from which the substrate 100 has been removed by the grinding process.

Furthermore, the method for manufacturing the semiconductor device according to the example embodiment may further include performing a sawing process along the additional passivation layer 162. In some example embodiments, the above-mentioned method may further include performing an EDS process or mapping measurement before performing sawing.

According to the above-described example embodiments, the structure in which the additional passivation layers are formed on the scribe line layers makes it possible to raise the threshold voltage of an insulator between the upper electrode layer and the scribe lines. Accordingly, when an EDS process or mapping measurement is performed on the semiconductor device, even if a high voltage of hundreds to thousands of volts is applied to the lower electrode layer, it is possible to prevent occurrence of sparks. Therefore, it is possible to prevent the semiconductor device from failing to reach a normal withstand voltage or being damaged while current flows by sparks.

While this invention has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A method for manufacturing a semiconductor device, the method comprising:
providing a substrate;
forming an epitaxial layer on the substrate;
defining a scribe line layer in the epitaxial layer;
forming an upper electrode layer on the epitaxial layer and the scribe line layer;
etching a portion of the upper electrode layer to expose the scribe line layer;
forming a main passivation layer on the upper electrode layer; and
forming an additional passivation layer on the scribe line layer.

2. The method for manufacturing the semiconductor device according to claim 1, the method further comprising:
forming active layers and termination layers on the epitaxial layer,
wherein forming the upper electrode layer includes forming the upper electrode layer on the active layers and the termination layers.

3. The method for manufacturing the semiconductor device according to claim 2, the method further comprising:
etching a portion of the upper electrode layer to expose some portions of the termination layers,
wherein forming the main passivation layer includes forming the main passivation layer on the upper electrode layer and the exposed portions of the termination layers.

4. The method for manufacturing the semiconductor device according to claim 3, the method further comprising:
etching a portion of the upper electrode layer to expose a portion of the epitaxial layer,
wherein forming the main passivation layer includes forming the main passivation layer on the upper electrode layer, the exposed portions of the termination layers, and the exposed portion of the epitaxial layer.

5. The method for manufacturing the semiconductor device according to claim 1, the method further comprising:
etching a portion of the main passivation layer to expose a portion of the upper electrode layer.

6. The method for manufacturing the semiconductor device according to claim 1, the method further comprising:
removing the substrate through a grinding process.

7. The method for manufacturing the semiconductor device according to claim 6, the method further comprising:
forming a lower electrode layer on the surface from which the substrate has been removed by the grinding process.

8. The method for manufacturing the semiconductor device according to claim 7, the method further comprising:
performing a sawing process along the additional passivation layer.

9. The method for manufacturing the semiconductor device according to claim 7, the method further comprising:
performing an EDS (electrical die sorting) process or mapping measurement before the sawing is performed.

10. The method for manufacturing the semiconductor device according to claim 1, wherein
forming the additional passivation layer includes deposing SiO₂ on the scribe line layer to a predetermined thickness to form the additional passivation layer.

11. A semiconductor device comprising:
a lower electrode layer;
an epitaxial layer that is formed on the lower electrode layer;
an upper electrode layer that is formed on a portion of the epitaxial layer;
a main passivation layer that is formed on another portion of the epitaxial layer and a portion of the upper electrode layer;
a first scribe line layer that is formed on a first side of the epitaxial layer on the lower electrode layer;
a first additional passivation layer that is formed on the first scribe line layer;
a second scribe line layer that is formed on a second side of the epitaxial layer on the lower electrode layer; and
a second additional passivation layer that is formed on the second scribe line layer.

12. The semiconductor device of claim 11, wherein
on the epitaxial layer, active layers are formed, and
on the active layer, the upper electrode layer is formed.

13. The semiconductor device of claim 12, wherein
on the epitaxial layer, termination layers are formed, and
on some portions of the termination layers, the upper electrode layer is formed, and
on the other portions of the termination layers, the main passivation layer is formed.

14. The semiconductor device of claim 11, wherein
the first additional passivation layer and the second additional passivation layer are formed by deposing SiO₂ on the first scribe line layer and the second scribe line layer to a predetermined thickness.
